(19) United States
(12) Patent Application Publication
(10) Pub. No.: US 2006/0056238 A1
(43) Pub. Date: Mar. 16, 2006

(54) Flash memory devices having a voltage trimming circuit and methods of operating the same

(76) Inventors: Jin-Sung Park, Gyeonggi-do (KR); Dae-Seok Byeon, Gyeonggi-do (KR)

Correspondence Address: D. Scott Moore;Myers Bigel Sibley & Sajovec, Post Office Box 37428, Raleigh, NC, 27627, US

(21) Appl. No.: 11/023,896

(22) Filed: Dec. 28, 2004

(30) Foreign Application Priority Data
Sep. 13, 2004 (KR) 2004-73033

(51) Int. Cl. G11C 11/34

(52) U.S. Cl. 365/185.22

(57) ABSTRACT

A flash memory device includes a trimming circuit that is configured to generate a plurality of identification voltages associated with a plurality of memory cell threshold voltage states, respectively, and to trim the plurality of identification voltages responsive to trimming information.

### RELATED APPLICATION

This application claims the benefit of and priority to Korean Patent Application No. 2004-73033, filed Sep. 13, 2004, the disclosure of which is hereby incorporated herein by reference.

### FIELD OF THE INVENTION

The present invention relates generally to integrated circuit devices and methods of operating the same and, more particularly, to flash memory devices and methods of operating the same.

### BACKGROUND OF THE INVENTION

Semiconductor memory devices are storage devices that contain data therein and allow the data stored therein to be read therefrom. Semiconductor memory devices may be classified into random access memory (RAM) devices and read only memory (ROM) devices. A RAM may be a volatile memory device that loses data in its memory cells when power supplied to the device is interrupted or suspended. A ROM may be a nonvolatile memory device that retains data in its memory cells even when power supplied to the device is shut down. A ROM may may be embodied in various ways, such as a programmable ROM (PROM), an erasable PROM (EPROM), an electrically EPROM (EEPROM), and/or a flash memory device.

Flash memory devices are generally of two types: a NAND-type flash memory device and a NOR-type flash memory device. Because a NOR-type flash memory device typically has a structure in which respective memory cells are independently connected to word lines and bit lines, it has a generally good access time characteristic. A cell array region of a NAND-type flash memory device may include a plurality of strings. A string typically includes a string selection transistor, a plurality of cell transistors, and a ground selection transistor, which are serially connected so as to use one contact per cell string. Accordingly, a NAND-type flash memory device typically has higher integration density and lower cell current as compared to a NOR-type memory device.

In a flash memory device, a memory cell typically includes a control gate and a floating gate. The memory cell is programmed by injecting electric charges into the floating gate and is erased by discharging the injected electric charge from the floating gate. To increase the integration density of a flash memory device, a technique called “multi-level cell” (hereinafter referred to as MLC) has been proposed in which two or more bits of data are stored in a single memory cell to thereby improve the storage capacity per cell. Unlike a MLC, a single-level cell (SLC) stores one bit per memory cell.

A conventional MLC has four threshold voltage states: “11”, “10, “00”, and “01”. Supposing a memory cell has threshold voltage distributions—2.7V or lower, 0.3V˜0.7V, 1.3V˜1.7V, and 2.3V˜2.7V, the threshold states “11”, “10”, “00”, and “01” correspond to the threshold voltage distributions—2.7V or lower, 0.3V˜0.7V, 1.3V˜1.7V, and 2.3V˜2.7V, respectively. That is, when a threshold voltage of the memory cell corresponds to one of the four threshold voltage ranges, two-bit data corresponding thereto are stored in the memory cell.

To read out the data stored in a MLC, three read voltages are used. During a programming operation for a MLC, three verifying voltages may be used to verify programmed data. If the MLC has eight threshold voltage states, seven read voltages and seven verifying voltages may be used.

However, the threshold voltage distribution profiles of a MLC can vary to undesirable values while manufacturing or using the MLC flash memory device. When the threshold voltage distribution profiles of memory cells change, a reading voltage or a verifying voltage may be trimmed. The threshold voltage distribution widths of a memory cell are similar to each other except a first state (for example, “11”) and a last state (for example, “01”). Although the threshold voltage distribution profiles may vary, intervals between the threshold voltage distribution profiles typically have the same value. Accordingly, it may be desirable to keep the differences between reading voltages, which determine the intervals between threshold voltage distributions, constant.

### SUMMARY OF THE INVENTION

According to some embodiments of the present invention, a flash memory device includes a trimming circuit that is configured to generate a plurality of identification voltages associated with a plurality of memory cell threshold voltage states, respectively, and to trim the plurality of identification voltages responsive to trimming information.

In other embodiments of the present invention, the trimming circuit comprises a fuse that stores the trimming information.

In still other embodiments of the present invention, the trimming circuit is further configured to trim the plurality of identification voltages by about the same magnitude responsive to the trimming information.

In still other embodiments of the present invention, the plurality of identification voltages comprises at least one reading data voltage for reading data that are stored in a memory cell.

In still other embodiments of the present invention, the plurality of identification voltages comprises at least one verifying data voltage for verifying data that are stored in a memory cell.

In still other embodiments of the present invention, the plurality of identification voltages comprises at least one reading data voltage for reading data that are stored in a memory cell and at least one verifying data voltage for verifying data that are stored in a memory cell.

In still other embodiments of the present invention, the plurality of memory cell threshold voltage states comprises four memory cell threshold voltage states.

In still other embodiments of the present invention, the plurality of identification voltages comprises three reading data voltages for reading data that are stored in a memory cell.

In still other embodiments of the present invention, the plurality of identification voltages comprises three verifying data voltages for verifying data that are stored in a memory cell.

In still other embodiments of the present invention, the plurality of identification voltages comprises three reading data voltages for reading data that are stored in a memory cell and three verifying data voltages for verifying data that are stored in a memory cell.

In further embodiments of the present invention, a flash memory device comprises a memory cell that is configured to be programmed with one of a plurality of memory cell threshold voltage states. A voltage generator is configured to generate a plurality of identification voltages associated with the plurality of memory cell threshold voltage states, respectively, and to trim the plurality of identification voltages responsive to trimming information. A selecting circuit is configured to couple one of the plurality of identification voltages to the memory cell. A control circuit is configured to provide the trimming information to the voltage generator responsive to a power-up signal.

Although described above primarily with respect to device embodiments of a flash memory, it will be understood that the present invention is not limited to such embodiments, but may also be embodied as methods of operating a flash memory device.

### BRIEF DESCRIPTION OF THE DRAWINGS

Other features of the present invention will be more readily understood from the following detailed description of specific embodiments thereof when read in conjunction with the accompanying drawings, in which:

FIG. 1 is a block diagram that illustrates flash memory devices according to some embodiments of the present invention;

FIG. 2 is a circuit schematic that illustrates a voltage trimming circuit shown in FIG. 1 in accordance with some embodiments of the present invention;

FIG. 3 is a diagram that illustrates a process in which a voltage for reading out data stored in a memory cell is trimmed in accordance with some embodiments of the present invention;

FIG. 4 is a diagram that illustrates a process in which a voltage for verifying data stored in a memory cell is trimmed in accordance with some embodiments of the present invention;

FIG. 5 is a circuit schematic of a voltage trimming circuit shown in FIG. 1 in accordance with further embodiments of the present invention; and

FIG. 6 is a diagram that illustrates a process for trimming a reading voltage or a verifying voltage using the voltage trimming circuit shown in FIG. 5 in accordance with some embodiments of the present invention.

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims. Like reference numbers signify like elements throughout the description of the figures.

As used herein, the singular forms “a,” “an,” and “the” are intended to include the plural forms as well, unless expressly stated otherwise. It will be further understood that the terms “includes,” “comprises,” “including,” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present. Furthermore, “connected” or “coupled” as used herein may include wirelessly connected or coupled. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

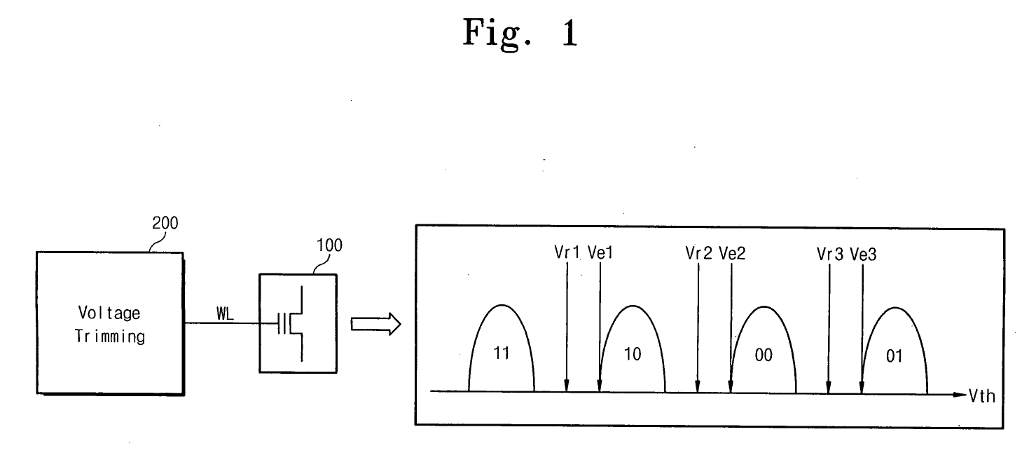

FIG. 1 is a block diagram that illustrates flash memory devices according to some embodiments of the present invention. As shown in FIG. 1, the flash memory device includes a memory cell 100 and a voltage trimming circuit 200. The memory cell 100 has one of 4 threshold voltage states: “11”, “10”, “00”, and “01”. The voltage trimming circuit 200 is connected to a word line WL of the memory cell 100, and provides a voltage for identifying the threshold voltage states to the word line WL.

As shown in FIG. 1, the voltages provided to the memory cell 100 may be Vr1, Vr2, and Vr3 for reading out data stored in the memory cell 100 and/or voltages Ve1, Ve2, and Ve3 for verifying programmed data after data are programmed in the memory cell 100.

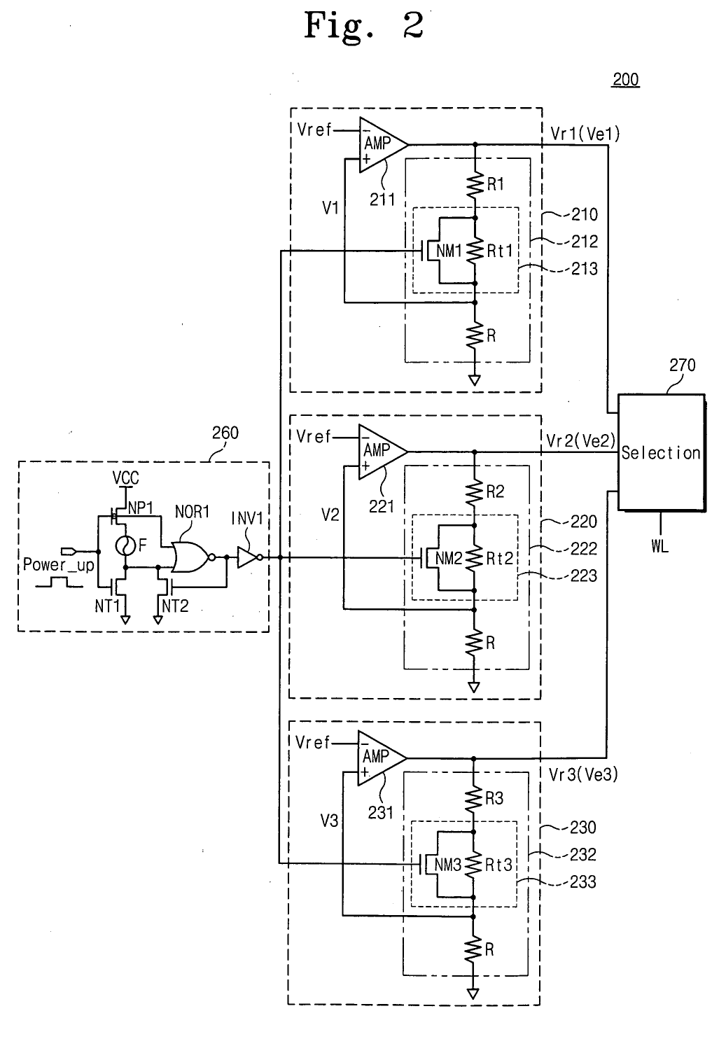

When a power-up operation is performed, the voltage trimming circuit 200 trims the reading voltages Vr1, Vr2, and Vr3 and/or the verifying voltages Ve1, Ve2, and Ve3 by a predetermined amplitude according to trimming information. An internal configuration and operation of the voltage trimming circuit 200, in accordance with some embodiments of the present invention, will be described with reference to FIG. 2.

FIG. 2 is a circuit schematic that illustrates a voltage trimming circuit shown in FIG. 1 in accordance with some embodiments of the present invention. As shown in FIG. 2, the voltage trimming circuit 200 includes first, second, and third voltage generators 210, 220, and 230, a control circuit 260, and a selecting circuit 270.

Respective voltage generators 210, 220, and 230 generate the reading voltages Vr1, Vr2, and Vr3, and/or the verifying voltages Ve1, Ve2, and Ve3 for identifying a threshold voltage state of the memory cell 100 (see FIG. 1).

The first voltage generator 210 includes an amplifier 211 and a voltage divider 212. The amplifier 211 has a negative (−) terminal and a positive (+) terminal. The amplifier 211 amplifies a voltage difference between the negative (−) terminal and the positive (+) terminal and outputs an amplified voltage. The negative (−) terminal of the amplifier 211 receives a reference voltage Vref from a reference voltage generator (not shown) and the positive (+) terminal thereof receives a divided voltage V1 from the voltage divider 212. The voltage divider 212 includes a first resistor R1 serially connected between an output terminal of the amplifier 211 and ground, a trimming circuit 213, and a second resistor R. The trimming circuit 213 includes an NMOS transistor NM1 and a trimming resistor Rt1 connected to each other in parallel. The divided voltage of the voltage divider 212 is a voltage of a node between the trimming circuit 213 and the second resistor R.

When the NMOS transistor NM1 is turned off, the voltage V1 is given by

$$V 1 = \frac{R}{R 1 + Rt 1 + R} Vr 1.$$

The amplifier 211 has the same voltage at both input terminals, i.e., V1=Vref. The reference voltage Vref may be substituted for voltage V1 in the equation,

$$Vref = \frac{R}{R 1 + Rt 1 + R} Vr 1.$$

Consequently, the reading voltage Vr1 generated by the first voltage generator 210 is expressed by equation (1).

$$Vr 1 = ( 1 + \frac{R 1}{R} + \frac{Rt 1}{R} ) Vref \qquad ( 1 )$$

When the NMOS transistor NM1 is turned on, a current flowing through the trimming resistor Rt1 is zero effectively short circuiting Rt1. Consequently, the reading voltage Vr1 generated by the first voltage generator 210 is expressed by equation (2).

$$Vr 1 = ( 1 + \frac{R 1}{R} ) Vref \qquad ( 2 )$$

Upon comparing equations (1) and (2), it can be seen that the trimming voltage Vr1 is trimmed by

$$( \frac{Rt 1}{R} ) Vref$$

by the trimming circuit 213. That is, the first voltage generator 210 turns the NMOS transistor NM1 off to allow the reading voltage Vr1 to be trimmed by

$$( \frac{Rt 1}{R} ) Vref .$$

Although described above with respect to the reading voltage Vr1, similar results may be obtained for the verifying voltage Ve1. Moreover, the second and third voltage generators 220 and 230 have the same internal structure and operation characteristic as those of the first voltage generator 210. Accordingly, the descriptions thereof are omitted. In the three voltage generators 210, 220, and 230, the trimming resistors Rt1, Rt2, and Rt3 have the same resistance value and the three reading voltages Vr1, Vr2, and Vr3 or three verifying voltages Ve1, Ve2, and Ve3 are trimmed by about the same magnitude.

The control circuit 260 includes a fuse F, a PMOS transistor NP1, two NMOS transistors NT1 and NT2, a NOR gate NOR1, and an inverter INV1. The control circuit 260 stores trimming information in the fuse F. Whether voltages generated by the three voltage generators 210, 220, and 230 are trimmed is determined according to a connecting state of the fuse F.

When the fuse F is connected or closed, the PMOS transistor NP1 and the NMOS transistor NT1 function as an inverter. Accordingly, when a power-up signal changes from a high level to a low level, two inputs of the NOR gate NOR1 have high and low levels and an output thereof becomes a low level. Consequently, the inverter INV1 outputs a control signal at a high level. When the control signal generated by the control circuit 260 has a high level, the NMOS transistors NM1, NM2, and NM3 of the three voltage generators 210, 220, and 230 are turned on, respectively.

When the fuse F is cut off or open, a junction node of the PMOS transistor NP1 and the NMOS transistor NT1 is in a floating state. At this time, when the power-up signal changes from a high level to a low level, the output of the NOR gate NOR1 becomes a high level. As a result, the inverter INV1 outputs a control signal at a low level. When the control signal generated by the control circuit 260 is at a low level, the NMOS transistors NM1, NM2, and NM3 of the three voltage generators 210, 220, and 230 are turned off, respectively. In this case, the three voltage generators 210, 220, and 230 generate voltages trimmed by a predetermined magnitude in comparison with the case in which the fuse F is connected.

The selecting circuit 270 selects one from the voltages generated by the three voltage generators 210, 220, and 230, and provides the selected voltage to a word line WL connected to the memory cell 100.

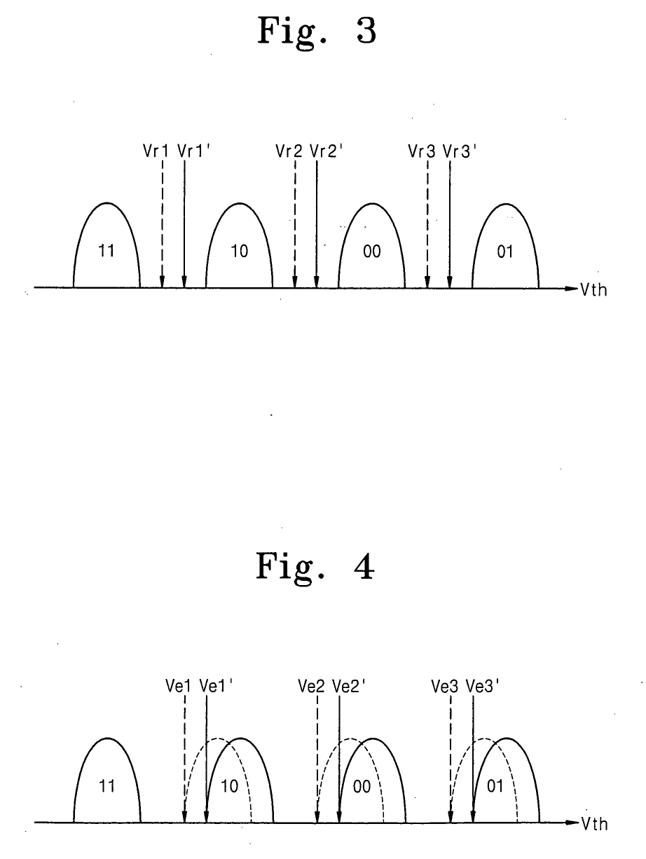

FIG. 3 is a diagram that illustrates a process in which a voltage for reading out data stored in a memory cell is trimmed in accordance with some embodiments of the present invention. As shown in FIG. 3, reading voltages Vr1, Vr2, and Vr3 may be trimmed to reading voltages Vr1′, Vr2′, and Vr3′, respectively, by cutting the fuse F (see FIG. 2). As further shown in FIG. 3, trimmed voltage amplitudes change according to resistance values of the trimming resistors Rt1, Rt2, Rt3 shown in FIG. 2. If the trimming resistors Rt1, Rt2, Rt3 have the same resistance value, the reading voltages are trimmed by about the same magnitude.

FIG. 4 is a diagram that illustrates a process in which a voltage for verifying data stored in a memory cell is trimmed in accordance with some embodiments of the present invention. As shown in FIG. 4, verifying voltages Ve1, Ve2, and Ve3 may be trimmed to verifying voltages Ve1′, Ve2′, and Ve3′, respectively, by cutting the fuse F (see FIG. 2). Trimmed voltage amplitudes of FIG. 4 have the same values as those shown in FIG. 3.

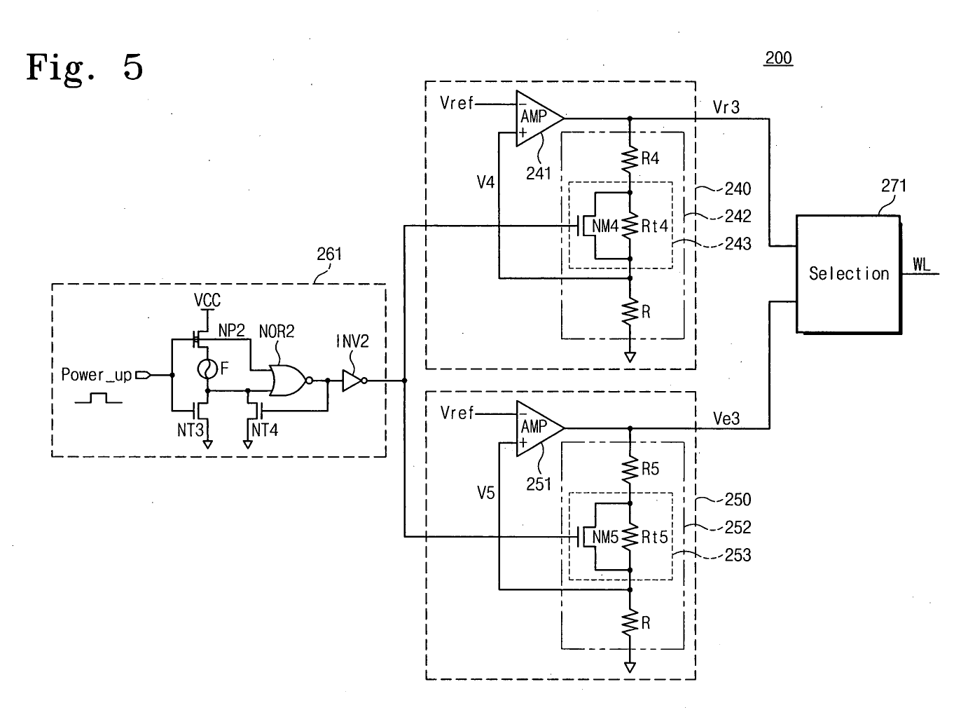

FIG. 5 is a circuit schematic of a voltage trimming circuit shown in FIG. 1 in accordance with further embodiments of the present invention. As shown in FIG. 5, the voltage trimming circuit 200 can trim a voltage for reading out data stored in the memory cell 100 (see FIG. 1) and a voltage for verifying the data stored in the memory cell 100 according to trimming information. Because the internal structure and operation of the voltage trimming circuit 200 shown in FIG. 5 can be understood from the description of FIG. 2 above, the descriptions thereof are omitted.

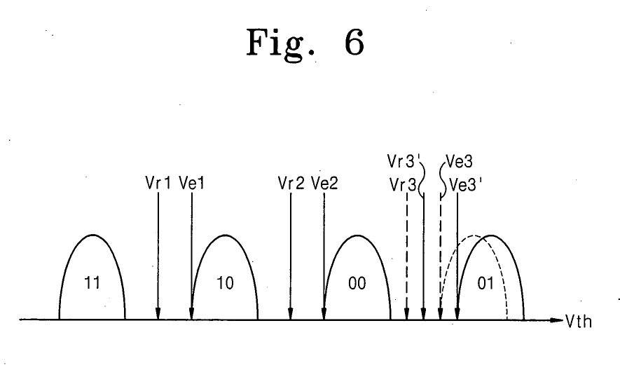

FIG. 6 is a diagram that illustrates a process for trimming a reading voltage or a verifying voltage using the voltage trimming circuit shown in FIG. 5 in accordance with some embodiments of the present invention. As shown in FIG. 6, a reading voltage Vr3 and a verifying voltage Ve3 are trimmed to a reading voltage Vr3′ and a verifying voltage Ve3′, respectively, by cutting the fuse F (see FIG. 5).

As shown in FIG. 6, trimmed voltage amplitudes change according to resistance values of the trimming resistors Rt4 and Rt5 shown in FIG. 5. If the trimming resistors Rt4 and Rt5 have the same resistance value, the reading and verifying voltages are trimmed by the same amplitude. Although described above with respect to the reading voltage Vr3 and the verifying voltage Ve3 in FIGS. 5 and 6, the same results may be obtained for the reading voltages Vr1 and Vr2, and the verifying voltages Ve1 and Ve2.

Although embodiments of the present invention have been described above with respect to a memory cell 100 having one of four threshold voltage states, it will be understood that other embodiments of the present invention may include a memory cell having more than four threshold voltage states (e.g., eight states).

As is apparent from the foregoing description, a flash memory device according to some embodiments of the present invention can trim the reading voltages or the verifying voltage for an MLC by a predetermined amplitude according to trimming information.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

1. A flash memory device, comprising:
a trimming circuit that is configured to generate a plurality of identification voltages associated with a plurality of memory cell threshold voltage states, respectively, and to trim the plurality of identification voltages responsive to trimming information.

2. The flash memory device as set forth in claim 1, wherein the trimming circuit comprises a fuse that stores the trimming information.

3. The flash memory device as set forth in claim 1, wherein the trimming circuit is further configured to trim the plurality of identification voltages by about the same magnitude responsive to the trimming information.

4. The flash memory device as set forth in claim 1, wherein the plurality of identification voltages comprises at least one reading data voltage for reading data that are stored in a memory cell.

5. The flash memory device as set forth in claim 1, wherein the plurality of identification voltages comprises at least one verifying data voltage for verifying data that are stored in a memory cell.

6. The flash memory device as set forth in claim 1, wherein the plurality of identification voltages comprises at least one reading data voltage for reading data that are stored in a memory cell and at least one verifying data voltage for verifying data that are stored in a memory cell.

7. The flash memory device as set forth in claim 1, wherein the plurality of memory cell threshold voltage states comprises four memory cell threshold voltage states.

8. The flash memory device as set forth in claim 7, wherein the plurality of identification voltages comprises three reading data voltages for reading data that are stored in a memory cell.

9. The flash memory device as set forth in claim 7, wherein the plurality of identification voltages comprises three verifying data voltages for verifying data that are stored in a memory cell.

10. The flash memory device as set forth in claim 7, wherein the plurality of identification voltages comprises three reading data voltages for reading data that are stored in a memory cell and three verifying data voltages for verifying data that are stored in a memory cell.

11. A flash memory device, comprising:
a memory cell that is configured to be programmed with one of a plurality of memory cell threshold voltage states;
a voltage generator that is configured to generate a plurality of identification voltages associated with the plurality of memory cell threshold voltage states, respectively, and to trim the plurality of identification voltages responsive to trimming information;
a selecting circuit that is configured to couple one of the plurality of identification voltages to the memory cell; and
a control circuit that is configured to provide the trimming information to the voltage generator responsive to a power-up signal.

12. The flash memory device as set forth in claim 11, wherein the control circuit comprises a fuse that stores the trimming information.

13. The flash memory device as set forth in claim 11, wherein the voltage generator is further configured to trim the plurality of identification voltages by about the same magnitude responsive to the trimming information.

14. The flash memory device as set forth in claim 11, wherein the plurality of identification voltages comprises at least one reading data voltage for reading data that are stored in a memory cell.

15. The flash memory device as set forth in claim 11, wherein the plurality of identification voltages comprises at least one verifying data voltage for verifying data that are stored in a memory cell.

16. The flash memory device as set forth in claim 11, wherein the plurality of identification voltages comprises at least one reading data voltage for reading data that are stored in a memory cell and at least one verifying data voltage for verifying data that are stored in a memory cell.

17. The flash memory device as set forth in claim 11, wherein the plurality of memory cell threshold voltage states comprises four memory cell threshold voltage states.

18. The flash memory device as set forth in claim 17, wherein the plurality of identification voltages comprises three reading data voltages for reading data that are stored in a memory cell.

19. The flash memory device as set forth in claim 17, wherein the plurality of identification voltages comprises three verifying data voltages for verifying data that are stored in a memory cell.

20. The flash memory device as set forth in claim 17, wherein the plurality of identification voltages comprises three reading data voltages for reading data that are stored in a memory cell and three verifying data voltages for verifying data that are stored in a memory cell.

21. A method of operating a flash memory device, comprising:
generating a plurality of identification voltages associated with a plurality of memory cell threshold voltage states, respectively; and
trimming the identification voltages responsive to trimming information.

22. The method as set forth in claim 21, further comprising:
coupling one of the plurality of identification voltages to a memory cell; and
providing the trimming information responsive to a power-up signal for the flash memory device.

23. The method as set forth in claim 21, wherein trimming the identification voltages comprises:
trimming the identification voltages by about the same magnitude responsive to the trimming information.

24. The method as set forth in claim 21, wherein the plurality of identification voltages comprises at least one reading data voltage for reading data that are stored in a memory cell.

25. The method as set forth in claim 21, wherein the plurality of identification voltages comprises at least one verifying data voltage for verifying data that are stored in a memory cell.

26. The method as set forth in claim 21, wherein the plurality of identification voltages comprises at least one reading data voltage for reading data that are stored in a memory cell and at least one verifying data voltage for verifying data that are stored in a memory cell.
